(19) United States
(12) Patent Application Publication
(10) Pub. No.: US 2014/0209277 A1
(43) Pub. Date: Jul. 31, 2014

(54) AIR DUCT

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: LEI LIU, Shenzhen (CN); GUO-YI CHEN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/771,033

(22) Filed: Feb. 19, 2013

(30) Foreign Application Priority Data
Jan. 28, 2013 (CN) 201310031011.1

(51) Int. Cl. H05K 7/20

(52) U.S. Cl. CPC H05K 7/20145
USPC 165/98

(57) ABSTRACT

An air duct includes a first frame and a guiding panel. The first frame includes a top wall and two sidewalls connected substantially perpendicularly to opposite sides of the top wall. Each sidewall defines a fixing hole adjacent to an end of the sidewall. The guiding panel includes a plate and two connecting pieces extending from a side of the plate. A pin protrudes from each connecting piece to be engaged in one of the fixing holes, thereby fixing the plate to the first frame. The plate is slanted relative to the top wall.

### BACKGROUND

1. Technical Field

The present disclosure relates to an air duct.

2. Description of Related Art

To dissipate heat generated by heat-generating elements, such as central processing units, of a motherboard, some heat dissipating apparatuses are mounted on the heat-generating elements. However, some small elements arranged nearby these heat-generating elements may not be cooled effectively.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of an air dust, together with a heat sink, shown in one state.

FIG. 2 is an exploded, isometric view of the air duct of FIG. 1.

FIG. 3 is similar to FIG. 1, but shown in another state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

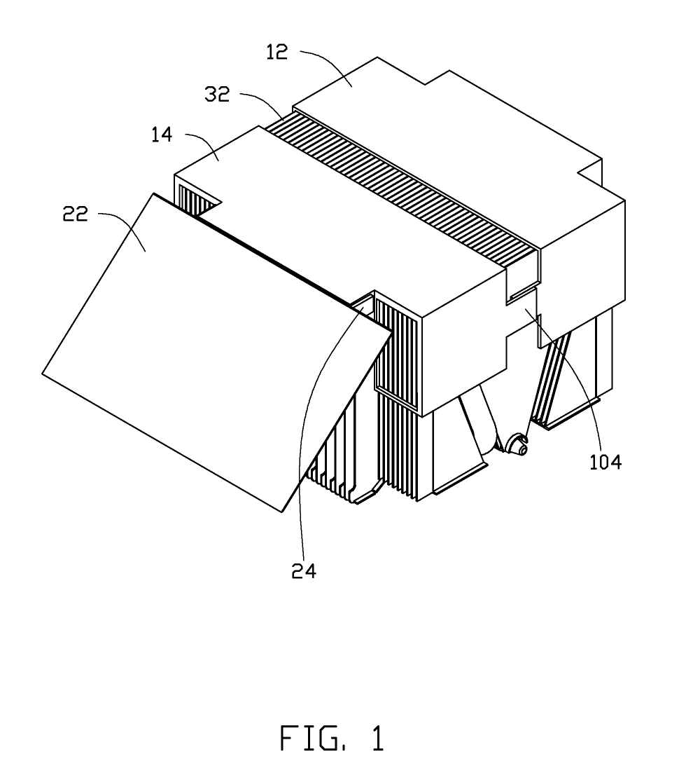

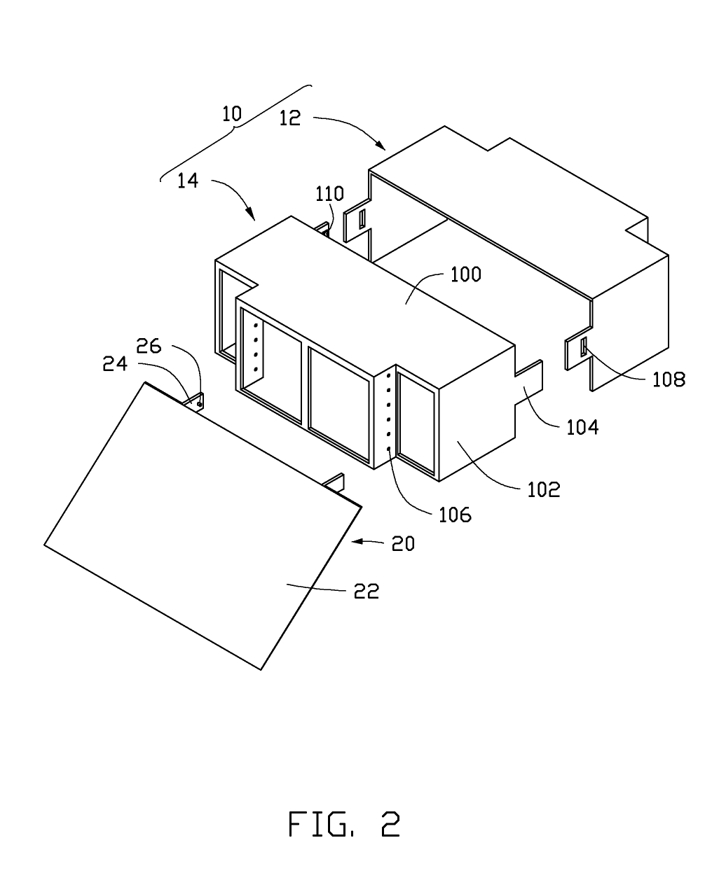

Referring to FIGS. 1 and 2, an embodiment of an air duct is mounted to a heat sink 32 mounted on a motherboard (not shown). The heat sink 32 is provided for dissipating heat generated by a central processing unit (CPU). A plurality of small electronic elements (not shown) is mounted on the motherboard adjacent to the CPU.

The air duct includes a main body 10 and a guiding panel 20.

The main body 10 includes a first frame 12 and a second frame 14. The first frame 12 and the second frame 14 each include a top wall 100, two sidewalls 102 extending substantially perpendicularly down from opposite ends of the top wall 100, and two latches 104 extending out from first sides of the sidewalls 104. Each sidewall 102 defines a plurality of vertically aligned fixing holes 106 in a second side of the sidewall 102 opposite to the corresponding latch 104. In particular, the latches 104 of the first frame 12 each define a through hole 108, the latches 104 of the second frame 14 each form a projection 110 to engage in a corresponding one of the through holes 108, thereby attaching the first frame 12 to the second frame 14.

The guiding panel 20 includes a plate 22 and two connecting pieces 24 extending out from a side of a bottom of the plate 22. The extension direction of the connecting pieces 24 is at an angle to the plate 22. A pin 26 protrudes from an inner surface of each connecting piece 24 facing the other connecting piece 24.

In assembly, the main body 10 is mounted to the heat sink 32. The pins 26 are engaged in two fixing holes 106 at a same height of the first frame 12 or the second frame 14, thereby fixing the guiding panel 20 to the first frame 12 or the second frame 14, with the bottom of the plate 22 facing slantingly downward. The plate 22 is slanted relative to the top wall 100, thereby guiding a part of the airflow downward to dissipate heat generated by the small electronic elements adjacent to the heat sink 32. The pins 26 are selectively engaged in two fixing holes 106 at a same height, thereby the height of the plate 22 is adjustable relative to the motherboard.

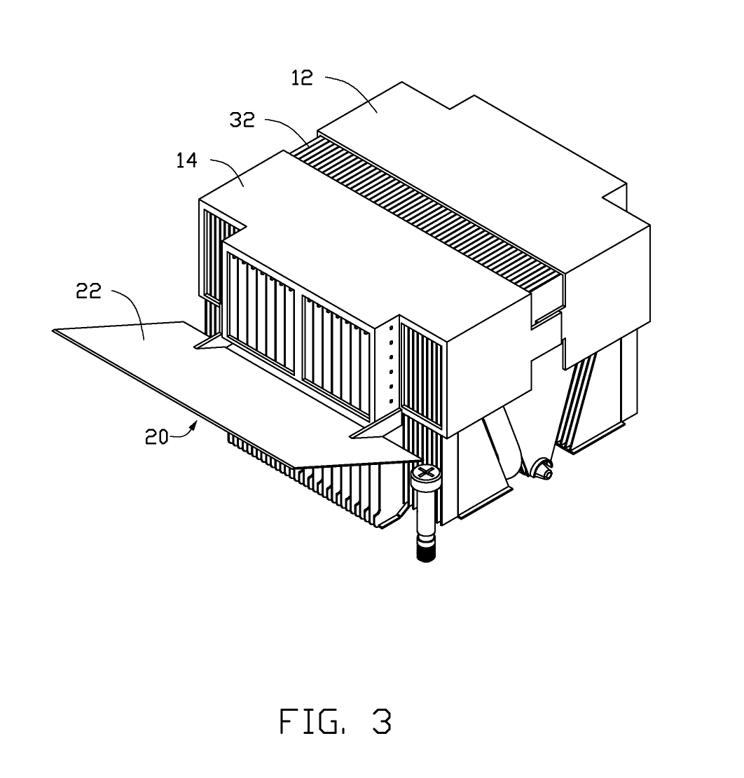

Referring to FIG. 3, in another state, the guiding panel 20 may be mounted to the main body 10, with the bottom of the plate 22 facing upward, thereby guiding a part of the airflow upward to dissipate to dissipate heat from electronic elements positioned higher than the heat sink 32, such as expansion cards (not shown).

It is believed that the present embodiments and their advantages will be understood from the foregoing description, and various changes may be made thereto without departing from the spirit and scope of the description or sacrificing all of their material advantages, the examples hereinbefore described merely being embodiments.

What is claimed is:

1. An air duct comprising a first frame and a guiding panel, wherein the first frame comprises a top wall and two sidewalls extending down from opposite sides of the top wall, each sidewall defines a fixing hole adjacent to a side of the sidewall, the guiding panel comprises a plate, two connecting pieces extending out from a side of the plate, and a pin protruding from an inner side of each connecting piece and engaging in one of the fixing holes, and the plate slants relative to the top wall of the first frame.

2. The air duct of claim 1, further comprising a second frame having substantially the same form as the first frame, a first latch extending out from each sidewall of the first frame, a second latch extending out from each sidewall of the second frame and defining a through hole, and a projection protruding from each of the first latches and engaging in a corresponding through hole.

3. The air duct of claim 1, wherein each sidewall of the first frame defines a plurality of vertically aligned fixing holes, and the pins are selectively engaged in two fixing holes at approximately the same height.
